(19) United States
(12) Patent Application Publication
(10) Pub. No.: US 2018/0067676 A1
(43) Pub. Date: Mar. 8, 2018

(54) STORAGE DEVICE

(71) Applicant: HITACHI, LTD., Tokyo (JP)

(72) Inventors: Wenhan SHI, Tokyo (JP); Masashi NAKANO, Tokyo (JP); Junji OGAWA, Tokyo (JP); Akira MATSUI, Tokyo (JP)

(73) Assignee: HITACHI, LTD., Tokyo (JP)

(21) Appl. No.: 15/558,063

(22) PCT Filed: Jun. 4, 2015
(86) PCT No.: PCT/JP2015/066212

§ 371 Date: Sep. 13, 2017

(51) Int. Cl. G06F 3/06; G06F 11/10; G06F 12/02; G11C 16/14

(52) U.S. Cl. CPC G06F 3/0632; G06F 3/0631; G11C 16/14; G06F 11/1076; G06F 12/0246; G06F 3/0689

(57) ABSTRACT

A storage device according to an aspect of the present invention comprises a plurality of memory devices and a storage controller. The memory devices provide the storage controller with a storage space which comprises a plurality of sectors, each said sector including a write data memory region and an inspection code memory region. When the memory devices receive a read request from the storage controller, if the sector which is the subject of the read request has not been written to, an inspection code is generated on the basis of information included in the read request, and data of a prescribed pattern is transmitted with the inspection code to the storage controller.

### TECHNICAL FIELD

The present invention relates to a storage device using a nonvolatile semiconductor memory.

### BACKGROUND ART

Along with the advancement of IT and spreading of the Internet, the amount of data handled by computer systems in companies is continuously increasing. Therefore, the capacity of storage systems used in organizations handling a large amount of data is also increasing.

In order to start using the storage system, it is necessary to initialize (format) a plurality of memory devices installed in the storage system. During initialization, a predetermined pattern data (such as all zero) is written to all memory areas of the memory devices. Thus, along with the increase in capacity of the storage system, an extremely long period of time is required for initialization. Since the storage system cannot be used until initialization is completed, it is not preferable for the system to require a long time for initialization.

In order to solve this problem, for example a storage system that performs initialization of a disk drive while receiving I/O requests from the host is disclosed in Patent Literature 1. According to this initialization method, initialization is executed in the background, and a predetermined data pattern such as all zero is written by initialization. When a host I/O is received, if the I/O target area is already initialized, a normal I/O is performed to that area. If initialization is not completed, and if the I/O is a write, data is written after executing initialization, but if the I/O is a read, the initialization data is returned to host. The process is executed by a storage controller, or a disk drive.

### CITATION LIST

### Patent Literature

[PTL 1] U.S. Pat. No. 7,461,176

### SUMMARY OF INVENTION

### Technical Problem

Some storage systems which require high reliability store an inspection code for enabling validity verification of data together with the data when data is written to the memory device. In such storage systems, a field for storing an inspection code (called DIF: Data Integrity Field) is provided in the memory area, in addition to the area for storing data. During data write, the storage system generates an inspection code, and stores the inspection code in the DIF. Generally, since an error detecting code computed based on write data and information that enables to verify validity of data access location (information computed based on data storage destination address) are stored in the inspection code, the content of the inspection code may vary depending on the stored location of data.

According to the initialization technique as disclosed in Patent Literature 1, a predetermined data pattern can be written into the memory area, but there is no consideration on storing information that differs depending on the data storage location. Therefore, it is difficult to introduce the technique taught in Patent Literature 1 to the storage system requiring high reliability.

### Solution to Problem

The storage device according to one aspect of the present invention includes a plurality of memory devices and a storage controller. The memory device provides a storage space having a plurality of sectors to the storage controller, and each sector is composed of a write data memory region and an inspection code memory region. When the memory device receives a read request from the storage controller, if a read target sector has not been written to, an inspection code is generated based on information included in the read request, and a predetermined pattern data and the inspection code are transmitted to the storage controller.

### Advantageous Effects of Invention

According to the present invention, the initialization process of the memory device can be made substantially unnecessary.

### BRIEF DESCRIPTION OF DRAWINGS

FIG. 1 is a hardware configuration diagram of a computer system including a storage system according to a preferred embodiment of the present invention.

FIG. 2 is a configuration diagram of FMPK.

FIG. 3 is an explanatory view of a RAID group.

FIG. 4 illustrates an example of data format.

FIG. 5 is a view illustrating a configuration of a logical-physical mapping table.

FIG. 6 is a view illustrating a configuration of a free page list.

FIG. 7 is a view illustrating a configuration of an uninitialized block list.

FIG. 8 is a flowchart of an initialization process.

FIG. 9 is a flowchart of a write process.

FIG. 10 is a flowchart of a read process.

### DESCRIPTION OF EMBODIMENTS

Now, a preferred embodiment of the present invention will be described with reference to the drawings. The embodiment described below are not intended to restrict the scope of the invention stated in the claims, and not all the elements and combinations of elements described below are indispensable in the means for solving the problems of the invention.

In the following description, the information in the present invention is described using descriptions such as “aaa table”, but the information can be described by data structures other than tables. The “aaa table” may also be referred to as “aaa information” to indicate that the information does not depend on the data structure. Further, information for identifying “bbb” of the present invention can be described as “bbb name”, but the information for identifying “bbb” is not restricted to names, and any information such as an identifier, an identification number or an address can be used, as long as “bbb” can be specified.

The following description may use the term “program” as subject, but actually, the program is executed by a processor (CPU: Central Processing Unit), and the processor executes determined processes using a memory and an I/F (interface). However, the term program may be used as the subject in the description, to prevent lengthy description. A part or all of the programs may be realized by a dedicated hardware. Various programs can be installed to respective devices from a program distribution server or a computer-readable storage media. Storage media can include, for example, IC cards, SD cards, DVDs and so on.

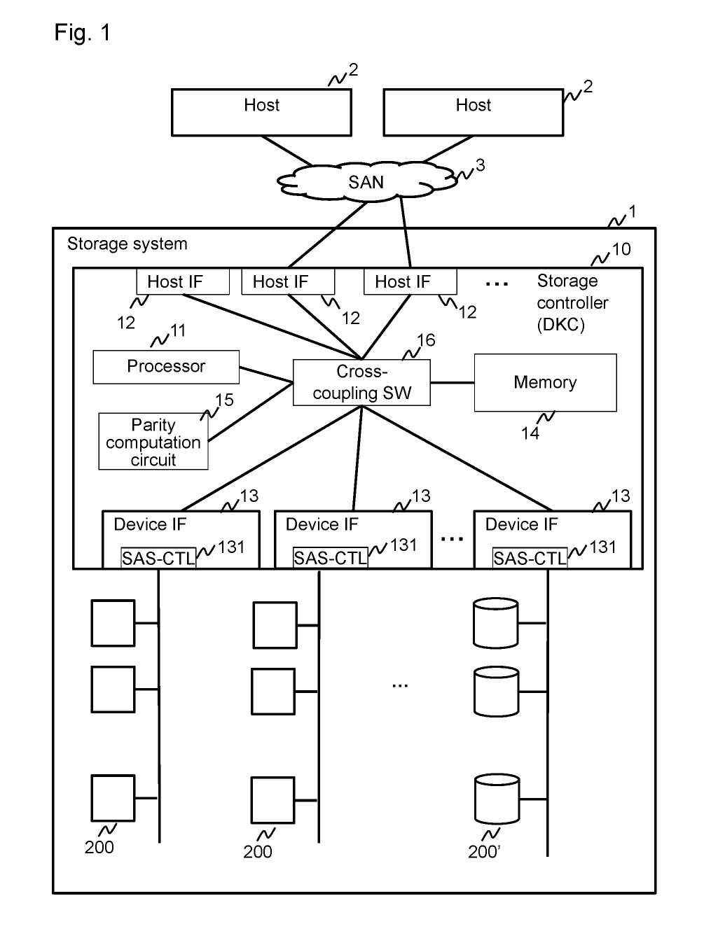

FIG. 1 illustrates a configuration of a computer system including a storage system 1 according to the present embodiment. The storage system, also referred to as storage device, 1 includes a storage controller, sometimes referred to as DKC, 10, and a plurality of memory devices (200 and 200′) connected to the storage controller 10.

The memory devices (200 and 200′) are used to store write data from a superior device such as a host 2. The storage system 1 according to the present embodiment can use, as the memory devices, HDDs (Hard Disk Drives) having magnetic disks as recording media, and FMPKs (Flash Memory PacKages) which are storage apparatuses using nonvolatile semiconductor memories, such as flash memories, as storage media. The actual configuration of the FMPK will be described later.

In the present embodiment, an example is illustrated of a case where the memory devices 200′ are the HDDs and the memory devices 200 are FMPKs. Therefore, the memory device 200 may be referred to as “the FMPK 200”, and the memory device 200′ may be referred to as “the HDD 200′”. However, memory devices other than HDDs or FMPKs can also be used as the memory devices (200 and 200′). In the present embodiment, the memory devices (200, 200′) communicate with the storage controller 10 in compliance with SAS (Serial Attached SCSI) standards.

One or more hosts 2 are connected to the DKC 10. The DKC 10 and the host 2 are connected via a SAN (Storage Area Network) 3 formed using Fibre Channel, for example.

The DKC 10 at least includes a processor 11, a host interface (denoted as “host IF” in the drawing) 12, a device interface (denoted as “device IF” in the drawing) 13, a memory 14, and a parity computation circuit 15. The processor 11, the host interface 12, the device IF 13, the memory 14, and the parity computation circuit 15 are interconnected via a cross-coupling switch (cross-coupling SW) 16. A plurality of these configuration elements can be respectively installed in the DKC 10 to ensure higher performance and higher availability. However, only one each of these configuration elements may be installed in the DKC 10.

The device IF 13 at least includes an interface controller 131 (denoted as “SAS-CTL” in the drawing) for communicating with the memory devices 200 and 200′, and a transfer circuit (not shown). The interface controller 131 is for converting a protocol (such as the SAS) used in the memory devices 200 and 200′ to a communication protocol (such as PCI-Express) used inside the DKC 10. In the present embodiment, since the memory devices 200 and 200′ perform communication in compliance with SAS standards, a SAS controller (hereinafter abbreviated as “SAS-CTL”) is used as the interface controller 131. In FIG. 1, only one SAS-CTL 131 is illustrated in each device IF 13, but a configuration can be adopted in which a plurality of SAS-CTLs 131 exist in one device IF 13.

The host interface 12 at least includes an interface controller and a transfer circuit (not shown), similar to the device IF 13. The interface controller is used to covert a communication protocol used between the host 2 and the DKC 10 (such as Fibre Channel) to a communication protocol used inside the DKC 10.

The parity computation circuit 15 is hardware for generating redundant data (parity) required in a RAID technique. An exclusive OR (XOR), a Reed-Solomon code and the like are examples of redundant data generated by the parity computation circuit 15.

The processor 11 processes I/O requests arriving from the host interface 12. The memory 14 is used for storing programs executed by the processor 11, or storing various management information of the storage system 1 used by the processor 11. The memory 14 is also used for temporarily storing I/O target data regarding the memory devices (200 and 200′). The memory 14 is composed of a volatile storage medium such as a DRAM or an SRAM, but the memory 14 can also be composed using a nonvolatile memory as another embodiment.

As described earlier, the storage system 1 according to the present embodiment can be equipped with multiple types of memory devices such as the FMPK 200 and the HDD 200′. However, unless denoted otherwise, we will describe the embodiment assuming a configuration where only the FMPKs 200 are installed in the storage system 1.

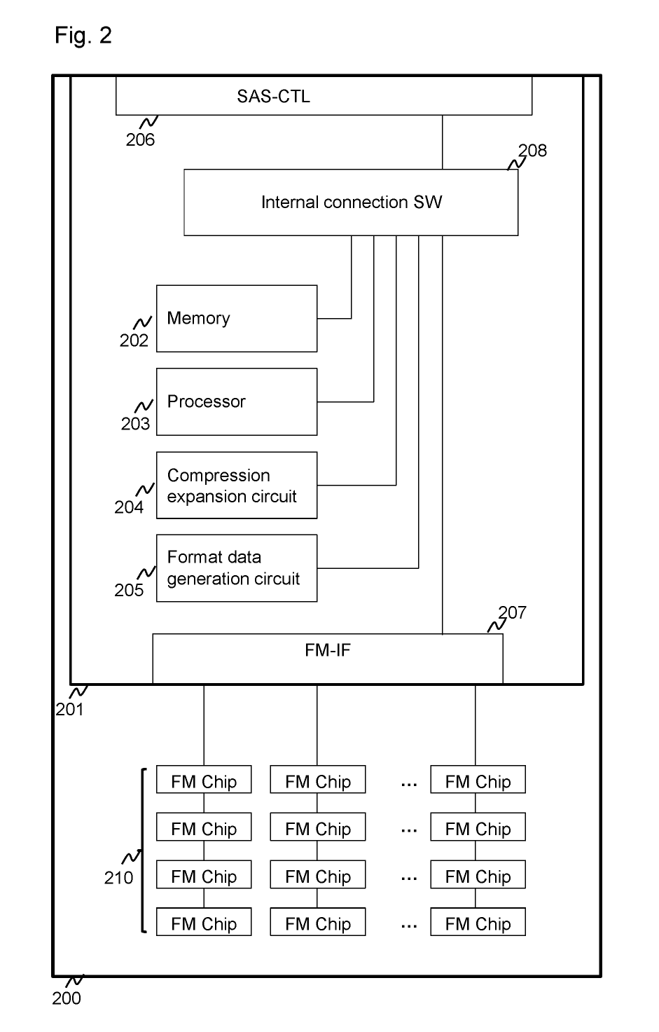

The configuration of the FMPK 200 will be described with reference to FIG. 2. The FMPK 200 is composed of a device controller (FM controller) 201, and a plurality of FM chips 210. The FM controller 201 includes a memory 202, a processor 203, a compression expansion circuit 204 for performing compression and expansion of data, a format data generation circuit 205 for generating format data, a SAS-CTL 206, and an FM-IF 207. The memory 202, the processor 203, the compression expansion circuit 204, the format data generation circuit 205, the SAS-CTL 206 and the FM-IF 207 are interconnected via an internal connection switch (internal connection SW) 208.

The SAS-CTL 206 is an interface controller for communicating between the FMPK 200 and the DKC 10. The SAS-CTL 206 is connected to the SAS-CTL 131 of the DKC 10 via a transmission line (SAS link). Further, the FM-IF 207 is an interface controller for communicating between the FM controller 201 and the FM chips 210.

The processor 203 executes processes related to various commands arriving from the DKC 10. The memory 202 stores programs executed by the processor 203, and various management information. A volatile memory such as a DRAM is used as the memory 202. However, a nonvolatile memory can also be used as the memory 202.

The compression expansion circuit 204 is a hardware equipped with a function for compressing data, or expanding compressed data. Data compression can also be performed by having the processor 203 execute a program for data compression, instead of providing the compression expansion circuit 204. If compression is not performed when storing the data to the FM chips 210, the compression expansion circuit 204 is not necessary.

The format data generation circuit 205 is hardware for generating initialization data. The processor 203 can be used instead of the format data generation circuit 205, by having the processor 203 execute a program for executing an equivalent process as the format data generation circuit 205.

The FM chips 210 are nonvolatile semiconductor memory chips such as NAND-type flash memories. As well known, the flash memory reads or writes data in units of pages, and data erase is performed in units of blocks, which are a set of pages. A page to which data has been written once cannot be overwritten, and in order to rewrite data to a page to which data has been written once, the whole block including the page must be erased. Therefore, the FMPK 200 provides a logical storage space to the DKC 10 to which the FMPK 200 is connected, without providing the memory area in the FM chips 210 as it is.

Next, we will describe the concept of the memory area used in the storage system 1. The storage system 1 forms a RAID (Redundant Arrays of Inexpensive/Independent Disks) group using a plurality of FMPKs 200. Then, in a state where failure occurs to one (or two) FMPK(s) 200 in the RAID group, the data in the FMPK 200 in which failure has occurred can be recovered by using data in the remaining FMPKs 200. Also, a part or all of the memory area in the RAID group is provided as logical volume to a superior device such as the host 2.

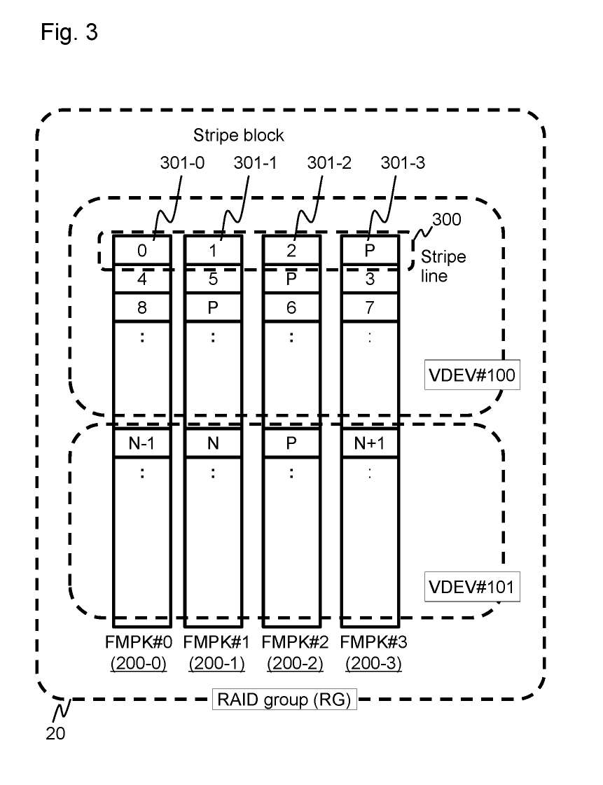

The memory area in the RAID group will be described with reference to FIG. 3. In FIG. 3, FMPK #0 through FMPK #3 respectively represent storage spaces that the FMPKs 200 (200-0 through 200-3) provide to the DKC 10. The DKC 10 constitutes one RAID group 20 from a plurality of (four in the example of FIG. 3) FMPKs 200, and divides the storage space in each FMPK (FMPK #0 (200-0) through FMPK #3 (200-3)) that belongs to RAID group 20 into a plurality of memory areas of fixed sizes, called stripe blocks.

Further, FIG. 3 illustrates an example in which the RAID level (representing a data redundancy method in a RAID technique, which generally includes RAID levels from RAID 1 to RAID 6) of the RAID group 20 is RAID 5. In FIG. 3, boxes denoted by “0”, “1” and “P” in the RAID group 20 represent stripe blocks, and the size of each stripe block is, for example, 64 KB, 256 KB, 512 KB, and so on. Further, a number such as “1” assigned to each stripe block is referred to as a “stripe block number”.

Among the stripe blocks in FIG. 3, the stripe block denoted by “P” represents a stripe block in which redundant data is stored, and this block is called a “parity stripe”. Meanwhile, the stripe blocks denoted by numerals (0, 1 and so on) are stripe blocks storing data (data that is not redundant data) written from superior devices such as the host 2. These stripe blocks are called “data stripes”.

According to the RAID group 20 illustrated in FIG. 3, for example, the stripe block located at a head of FMPK #3 (200-3) is parity stripe 301-3. When the DKC 10 creates redundant data to be stored in the parity stripe 301-3, the redundant data is generated by executing a predetermined calculation (such as exclusive OR (XOR)) to data stored in the data stripes (stripe blocks 301-0, 301-1, 301-2) located at the head of each FMPK 200 (FMPK #0 (200-0) through FMPK #2 (200-2)).

Now, a set (for example, element 300 of FIG. 3) composed of a parity stripe and data stripes used for generating redundant data to be stored in the relevant parity stripe is called a “stripe line”. In the case of the storage system 1 according to the present embodiment, like the stripe line 300 illustrated in FIG. 3, the stripe lines are configured based on a rule that each stripe block belonging to one stripe line exists at the same location (address) in the storage space of FMPKs 200-0 through 200-3.

The stripe block number described earlier is a number assigned to a data stripe, and it is a number unique within the RAID group. As illustrated in FIG. 3, the DKC 10 assigns numbers 0, 1 and 2 to each of the data stripes included in the initial stripe line within the RAID group. Further, consecutive numbers such as 3, 4, 5 and so on are assigned to data stripes included in the subsequent stripe lines, as illustrated in FIG. 3. Hereafter, the data stripe having a stripe block number n is an integer equal to or greater than 0) is referred to as “data stripe n”.

The storage system 1 according to the present embodiment divides and manages the memory area of the RAID group 20. Each divided memory area is called a virtual device (VDEV). Note that entire memory area in one RAID group 20 may be managed as one VDEV. An identification number unique within the storage system 1 is assigned to each VDEV. This identification number is called a VDEV number (or VDEV #). Also, the VDEV whose VDEV # is n is referred to as “VDEV # n”. In the present embodiment, VDEV # is an integer that is equal to or greater than 0 and that is equal to or smaller than 65535, in other words, a value within the range capable of being expressed by a 16-bit binary number.

Further, the storage system 1 according to the present embodiment divides the memory area of the VDEV, and provides the memory area having removed the parity stripes from the divided memory area to the host 2. The memory area provided to the host 2 is called a logical device (LDEV). Similar to the VDEV, an identifier unique within the storage system 1 is also assigned to each LDEV. This identifier is called an LDEV number (or LDEV #). When the host 2 performs write/read of data to/from the storage system 1, it issues a write command or a read command designating the LDEV # (or other information capable of deriving the identifier of the LDEV, such as a LUN).

In addition to the LDEV #, an address of an access target area within the LDEV (hereinafter, this address is called “LDEV LBA”) is included in the command (write command or read command). When the DKC 10 receives a read command, it converts the LDEV # and the LDEV LBA to the VDEV # and the address on the storage space of the VDEV (hereinafter, this address is called “VDEV LBA”). Further, the DKC 10 computes the identifier of the FMPK 200 and the address on the FMPK 200 (hereinafter, this address is called “FMPK LBA”) from the LDEV # and the LDEV LBA, and uses the computed FMPK LBA to read data from the FMPK 200.

Further, when the DKC 10 receives a write command, it computes the FMPK LBA of the FMPK 200 to which the parity corresponding to the write target data is to be stored, in addition to the FMPK LBA of the FMPK 200 to which the write target data is to be stored.

Next, we will describe a format of the data stored in the FMPK 200. A minimum unit in which the host 2 accesses the data stored in the storage space in the LDEV is, for example, 512 bytes. If the storage controller 10 receives a write command and write data to be written to the LDEV from the host 2, the storage controller 10 adds an eight-byte inspection code for every 512-bytes of data. In the present embodiment, this inspection code is called DIF. In the present embodiment, a chunk of 520-byte data composed of 512-byte data and the DIF added thereto, or the area storing this 520-byte chunk, is called a “sector”.

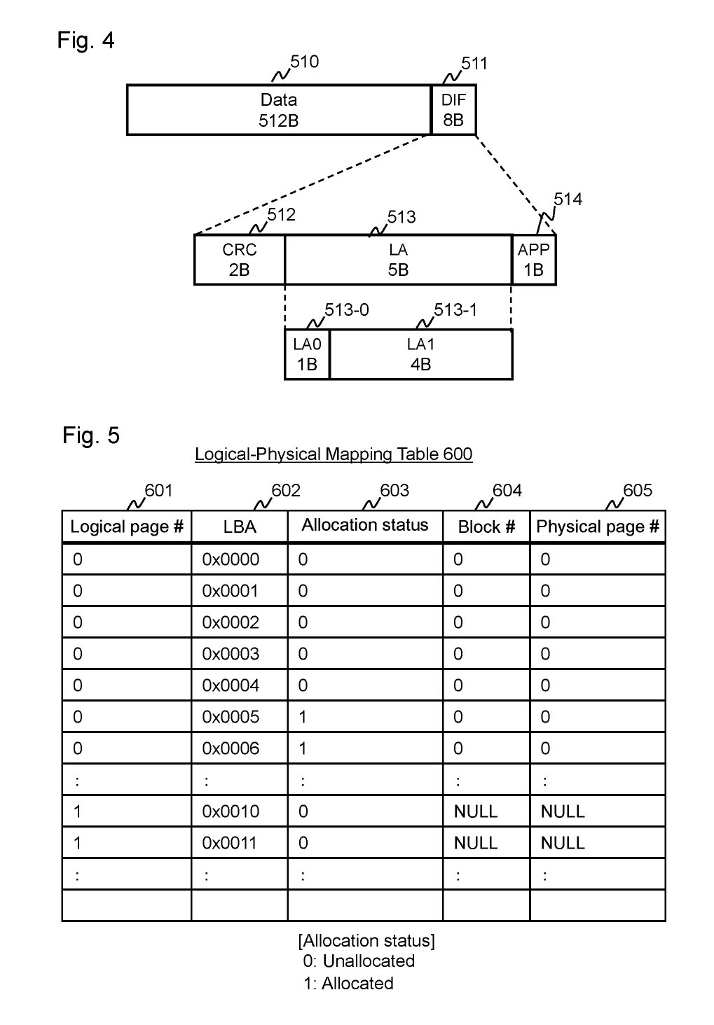

The format of a sector will be described with reference to FIG. 4. The sector is composed of a data 510 and a DIF 511. The data 510 is an area in which the write data received from the host 2 is stored, and the DIF 511 is an area in which the DIF added by the storage controller 10 is stored.

The DIF 511 includes three types of information, which are a CRC 512, an LA 513 and an APP 514. The CRC 512 is an error detecting code (CRC (Cyclic Redundancy Check) is used as an example) generated by performing a predetermined calculation to the data 510, and it is a 2-byte information.

The LA 513 is a 5-byte information generated based on the data storage location. An initial byte of the LA 513 (hereinafter called “LA0 (513-0)”) stores information having processed the VDEV # of the storage destination VDEV of the data 510. The remaining 4 bytes (called “LA1 (513-1)”) store information having processed a storage destination address (FMPK LBA) of the data 510. If the storage controller 10 receives a write request from the host 2, it generates information to be stored in LA0 (513-0) and LA1 (513-1) by specifying the VDEV # of the write data storage destination, and the set of FMPK and FMPK LBA of the write data storage destination, based on the data write destination address contained in the write request.

The APP 514 is a kind of error detecting code, and it is 1-byte information. The APP 514 is an exclusive OR of the respective bytes of data 510, CRC 512 and LA 513.

When the storage controller 10 tries to reads data from the FMPK 200, both the data 510 and the DIF 511 are sent to the storage controller 10. The storage controller 10 performs a predetermined calculation to the data 510 to calculate CRC. Then, the storage controller 10 judges whether the calculated CRC matches the CRC 512 in the DIF 511 (hereinafter, this judgment is called “CRC check”). If they are not equal, it means that the contents of data have been changed due to causes such as failure that has occurred during transfer of data from the FMPK 200. Therefore, if they are not equal, the storage controller 10 determines that data has not been read correctly.

Further, when data is read from the FMPK 200, the storage controller 10 judges whether the information included in the LA0 (513-0) matches the VDEV # to which the read target data belongs correspond. Further, it executes a predetermined calculation (described later) to the address (FMPK LBA) and the like included in the read command issued to the FMPK 200, and judges whether the result matches the LA1 (513-1) (hereinafter, this judgement is called “LA check”). If they are not equal, the storage controller 10 determines that the data has not been read correctly.

Next, we will describe the management information included in the FMPK 200, and the programs executed by the FMPK 200. At first, the management information will be described. The FMPK 200 includes management information of at least a logical-physical mapping table 600, a free page list 700, and an uninitialized block list 800.

FIG. 5 is a configuration example of the logical-physical mapping table 600. The logical-physical mapping table 600 includes columns of a logical page #601, an LBA 602, an allocation status 603, a block #604, and a physical page #605. Each record stores information related to the sector of the FMPK 200. The logical-physical mapping table 600 is stored in the memory 202. As another embodiment, the table can be stored in a part of the area in the FM chips 210.

The LBA 602 indicates the LBA of the sector, and the logical page #601 stores a logical page number of a logical page to which the sector belongs. The physical page #605 stores an identification number (physical page number) of the physical page mapped to the logical page to which the sector belongs, and the block #604 stores an identification number (block number) of a block to which the physical page belongs. In a state where a physical page is not mapped to a logical page, an invalid value (NULL) is stored in the block #604 and the physical page #605 of all sectors of the logical page. A minimum unit of write of the flash memory is a page. Therefore, even if a write to a portion of the logical page is requested from the DKC 10, one physical page is mapped to a logical page. When a physical page is mapped to a logical page, a block number of the block to which the mapped physical page belongs and a physical page number of the mapped physical page are respectively stored in the block #604 and the physical page #605 of all sectors of this logical page.

The allocation status 603 stores information indicating that there has been a write to the sector specified by the LBA 602. If data write is performed to the sector, “1” is stored in the allocation status 603. If there has been no data write, “0” is stored.

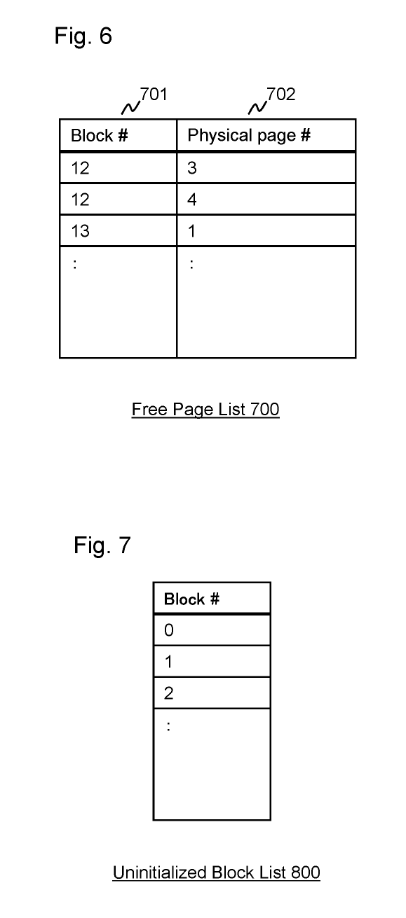

A physical page is mapped to the logical page only after there is a write to the logical page from the DKC 10. Since a physical page cannot be rewritten unless an erase process is performed, when the FM controller 201 maps a physical page to the logical page, it maps a physical page that has not yet been written (unused physical page). Therefore, the FM controller 201 stores information of all unused physical pages within the FMPK 200 in the free page list 700 (FIG. 6) and manages them. A block number of a block to which an unused physical page belongs and a physical page number of the unused physical page are respectively stored in block #701 and physical page #702 of the free page list 700.

FIG. 7 illustrates a configuration of the uninitialized block list 800. The uninitialized block list 800 is management information that the FMPK 200 uses during the initialization process. The uninitialized block list 800 stores a list of block numbers of blocks necessary for performing erase process when performing the initialization process.

Next, we will describe an initialization process of the FMPK 200 performed in the storage system 1 according to the present embodiment. The DKC 10 forms a RAID group using a plurality of FMPKs 200, and uses the formed RAID group to define one or more VDEVs. Further, the DKC 10 uses the VDEV to define one or more LDEVs.

The FMPK 200 used for forming the RAID group can be an unused FMPK 200 that has been newly installed to the storage system 1, or it can be an FMPK 200 that had been used for other purposes in the past. Therefore, arbitrary data may be stored in the respective FMPKs 200 constituting the RAID group immediately after forming the RAID group. In order to enable data to be recovered by a RAID technique when failure occurs to the FMPK 200, appropriate information should be stored in the data stripes and the parity stripes of the RAID group to which the LDEV (VDEV) belongs at a point of time when the LDEV (VDEV) is defined. In other words, in the parity stripe(s) of each stripe line, redundant data (parity) generated from all data stripes in the same stripe line must be stored.

Therefore, the storage system 1 according to the present embodiment initializes the RAID group by setting all areas (excluding the portion in which DIF is stored) of the data stripes and parity stripes in the memory devices 200 and 200′ constituting the RAID group to 0. During initialization of the RAID group, appropriate information is stored in the DIF of each stripe block. The DKC 10 transmits an initialization command to each of the FMPKs 200 constituting the VDEV to make each of the respective FMPKs 200 perform initialization. However, as will be described later, 0 is not actually stored in the memory areas (FM chips 210), and each FMPK 200 merely creates a state in which all zero data is virtually stored in the memory areas. Since data (all zero data) is not actually written to the memory area, the time required for the initialization process is substantially 0.

Next, the process flow of each program executed in the FMPK 200 will be described. At least an initialization program, a read program and a write program are executed in the FMPK 200. The initialization program is a program for initializing the FMPK 200, and it creates a state where no data is stored in each sector in the FMPK 200. In response to the administrator (user) of the storage system 1 using a management terminal (not shown) connected to the storage system 1 to issue an instruction to the storage system 1 to initialize the LDEV or the VDEV, the processor 11 of the storage controller 10 starts initializing the LDEV or the VDEV. The processor 11 issues an initialization command to each of the FMPKs 200 constituting the LDEV or the VDEV. The processor 203 of the FMPK 200 starts executing the initialization program in response to receiving an initialization command from the storage controller 10.

The read program is a program for executing the process related to the read command received from the DKC 10. The write program is a program for executing the process related to the write command received from the DKC 10.

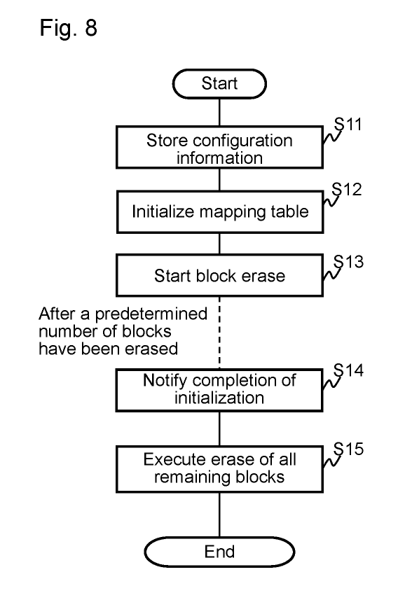

At first, the flow of the initialization process executed by the FMPK 200 will be described with reference to FIG. 8. When the FMPK 200 receives an initialization command from the storage controller 10, the initialization program is started in the processor 203. At first, the initialization program acquires configuration information transmitted with the initialization command, and stores the same in the memory 202 (S11). The details of the configuration information will be described later.

Next, the initialization program initializes the management information (S12). Specifically, the allocation status 603 in every record in the logical-physical mapping table 600 is set to 0, and the block #604 and the physical page #605 in every record are set to NULL. Moreover, all the information of the physical page stored in the free page list 700 is erased. Then, the block numbers of all blocks in the FMPK 200 are registered in the uninitialized block list 800.

Thereafter, the initialization program starts erasing the blocks whose block number is registered in the uninitialized block list 800 (S13). At this time, for example, if erasing of a block whose block number is X (hereinafter, referred to as “block # X”) is completed, the initialization program erases block # X from the uninitialized block list 800, and registers block numbers and physical page numbers of all physical pages belonging to block # X in the free page list 700.

When erasing of a predetermined number of blocks is completed, the initialization program sends a message stating that initialization has been completed to the storage controller 10 (S14). Only a part of blocks among the blocks within the FMPK 200 should be erased before S14. If the storage controller 10 receives a message from the FMPK 200 stating that initialization has been completed, it can issue a read command or a write command to the FMPK 200. Since the FMPK 200 notifies the storage controller 10 that initialization has been completed at a point of time when the management information has been initialized and a few blocks have been erased, the FMPK 200 will be in an initialization completed state in an extremely short time.

Even after S14, the initialization program continues to erase the blocks having block numbers registered in the uninitialized block list 800 (S15). When erasing of all the blocks registered in the uninitialized block list 800 is completed, the execution of the initialization program terminates.

The block erase process of S13 and S15 is not an indispensable process. It is possible that the initialization program does not erase blocks and that erasing blocks is done only if there is no free physical page when a write command has been received from the DKC 10 to the FMPK 200. However, if the FMPK 200 starts receiving write commands from the DKC 10 without performing S13, it becomes necessary to execute block erase before storing the write data received from the DKC 10, and the performance during write is deteriorated (response time is elongated). Therefore, the FMPK 20 according to the present embodiment erases a predetermined number of blocks in advance so that it can immediately (without executing block erase) store the write data from the storage controller 10 into the physical page.

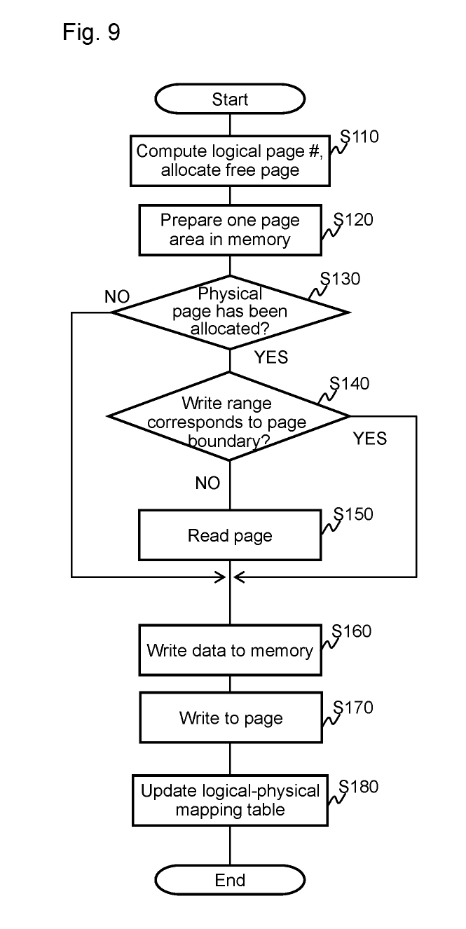

Next, the flow of write process that the FMPK 200 executes when it receives a write command from the DKC 10 will be described with reference to FIG. 9. The minimum unit of write when the DKC 10 writes data to the FMPK 200 is a sector. Meanwhile, a minimum unit of write when the FMPK 200 writes data to the FM chips 210 is a page (physical page), and the page size is a multiple of the sector size (page size is greater than sector size). Therefore, if the size of the area designated in the write command from the DKC 10 is smaller than one page, the FMPK 200 performs write in page units to the FM chips 210 by executing a so-called read-modify-write.

When the FMPK 200 receives a write command, the processor 203 starts executing the write program. In S110, the write program calculates the logical page # of the data write destination logical page by using the information of LBA and data length included in the write command. Further, in S110, the write program allocates an unused page from the free page list 700. Further, if a physical page (unused page) is not registered in the free page list 700, the write program creates unused page(s) by erasing the block registered in the uninitialized block list 800 before allocating an unused page. The information of the unused page(s) which were created is registered in the free page list 700.

A plurality of data write destination logical pages may be specified in S110. If a plurality of data write destination logical pages are specified, the write program allocates multiple unused pages. However, in the following description, an example is illustrated of a case where one logical page is specified in S110, and the specified logical page # is n (n is an integer equal to or greater than 0).

Next, the write program allocates an area having a size corresponding to one page (hereinafter called “buffer”) on the memory 202 (S120). The initialization of the contents in the buffer (such as writing 0) may or may not be performed.

In S130, the write program judges whether a physical page has already been mapped to a data write destination logical page. This can be judged by whether non-NULL value is stored in the physical page #605 (and the block #604) in the row where the logical page #601 is n in the logical-physical mapping table 600. If the physical page #605 (and the block #604) is NULL, it means that no physical page is mapped to the data write destination logical page (S130: No). In that case, the write program skips S140 and S150 and performs process of S160 and thereafter.

On the other hand, if the physical page #605 (and the block #604) is not NULL, a physical page is mapped to the data write destination logical page (S130: Yes). In that case, the write program judges whether the write range designated by the write command corresponds to the logical page boundary (S140). If the write range corresponds to the logical page boundary (that is, if the start LBA of the write target area is equal to the LBA of the initial sector in the logical page, and an end LBA of the write target area is equal to the LBA of the end sector in the logical page), the process of S150 is not performed. Meanwhile, if the write range does not correspond to the logical page boundary (S140: No), the write program reads data from the physical page mapped to the logical page, and stores the data in the buffer allocated in S120 (S150).

In S160, the write program overwrites the write data received together with the write command in the buffer allocated in S120. As described earlier, DIF is added to every 512-byte data by the DKC 10 to the write data received together with the write command from the DKC 10. Next, the write program stores the data in the buffer to the physical page allocated in S110 (S170).

Finally, in S180, the write program updates the logical-physical mapping table 600. Specifically, the write program stores the physical page number and the block number of the physical page allocated in S110 to the physical page #605 and the block #604 of the row whose logical page #601 is n in the logical-physical mapping table 600. Further, the write program changes the allocation status 603 to “1” of the row whose LBA 602 in the logical-physical mapping table 600 is included in the access range designated by the write command. If these processes are completed, the write program ends the write process.

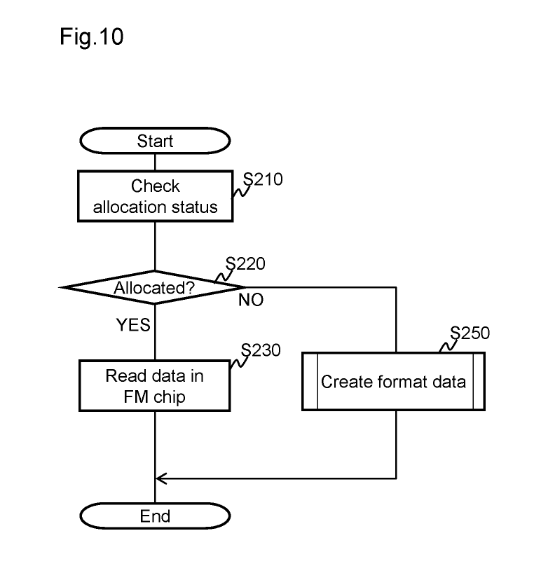

Next, the flow of read process that the FMPK 200 executes when it receives a read command from the DKC 10 will be described with reference to FIG. 10. The minimum read unit when the DKC 10 performs data read from the FMPK 200 is a sector.

When the FMPK 200 receives a read command, the processor 203 starts executing the read program. In S210, the read program checks whether the access range designated by the read command is an area where data write has already been performed in the past. Specifically, if the allocation status 603 in the record among the records in the logical-physical mapping table 600 whose LBA 602 is included in the access range designate by the read command is “1”, it means that the area has already been written to in the past. In the following description, in order to prevent lengthy description, an example is described of a case where reading the area of one sector is designated by the read command.

If the allocation status 603 of the row included in the access range designated by the read command is “1” (S220: Yes), the read program reads data from the physical page in which the read target data is stored, and stores the same in the memory 202. The minimum read unit of the FM chips 210 is a page (physical page), so in this example, data corresponding to one page is read. The read program extracts data being the read target in the read command from the data corresponding to one page which was read out to the memory 202, returns the same to the DKC 10 (S230), and ends the read process.

If the allocation status 603 of the row included in the access range designated by the read command is “0” (S220: No), the read program uses the format data generation circuit 205 to create the format data in the memory 202 (S250). The method of creating format data will be described later. Then, the created data is returned to the DKC 10 and ends the read process.

In the above description, an example has been described of a case where the access range designated by the read command is one sector, but a similar process is performed even when the access range is extended to multiple sectors. If the access range extends to a plurality of sectors, a sector that was written in the past and a sector that has never been written are included in the access range area. In that case, the sector that was written in the past should be subjected to the process of S230 described above, and the sector that has never been written should be subjected to the process of S250 described above.

Finally, the method for creating a format data performed in S250 will be described. In the present embodiment, the data storing a predetermined data pattern in the data 510 of FIG. 4 is called “format data”. All zero (where all bits are zero) is an example of the data pattern. In the following description, an example of creating a format data storing all zero in data 510 will be described.

During creation of format data, the information of the VDEV and the FMPK LBA to which the data 510 belongs is stored in the LA 513. These information are included in the configuration information received from the DKC 10 during initialization process, and in S250, the LA 513 is created using the configuration information. The configuration information received from the DKC 10 is described with reference to FIG. 3. In the example of FIG. 3, VDEV #100 and VDEV #101 are defined in the RAID group composed of the FMPK #0 (200-0) through FMPK #3 (200-3). The FMPKs 200 belonging to the RAID group receive, as configuration information, VDEV #s (101 and 101), a set of address and size (number of sectors) of the area belonging to VDEV #100 among the areas within the FMPKs 200, and a set of address and size (number of sectors) of the area belonging to VDEV #101 among the areas within the FMPKs 200.

### (1) Stored Content in Data 510

As described above, all zero is stored. All zero is stored both in the data 510 of the data stripes and the data 510 of the parity stripes. This is because if a parity is generated using data stripes storing all zero data, the contents will be all zero.

### (2) Stored Content in CRC 512

If all zero is stored in the data 510, the value of the CRC 512 (that is, the CRC generated from the data 510) also becomes zero. Therefore, all zero is stored in the CRC 512.

### (3) Stored Content in LA0 (513-0)

In S250, the format data generation circuit 205 specifies the VDEV to which the LBA designated by the read command belongs using the configuration information and the LBA information designated by the read command. Thereafter, the VDEV # of the specified VDEV is stored in LA0 (513-0). In the present embodiment, since the VDEV # is a 16-bit size value, the VDEV # is stored in LA0 (513-0) after it is processed so that it fits in LA0 (513-0) having a one-byte area. As an example, the format data generation circuit 205 extracts upper 8 bits and lower 8 bits, and stores 8-bit information, which is obtained by computing the logical sum of both of the upper 8 bits and the lower 8 bits, into LA0 (513-0). However, other storage formats can be adopted.

### (4) Stored Content in LA1 (513-1)

In LA1 (513-1), a remainder obtained by dividing the LBA (FMPK LBA) designated by the read command by the size (the number of sectors) of the area in the FMPK 200 included in the VDEV to which the LBA designated by the read command belongs is stored. For example, if the LBA designated by the read command belongs to VDEV #100 and the size of the area belonging to VDEV #100 (the number of sectors) among the areas of the FMPK 200 is m, the remainder obtained by dividing the LBA designated in the read command by in is stored.

### (5) Stored Content in APP 514

In S250, the format data generation circuit 205 calculates the exclusive OR of respective bytes of the data 510, the CRC 512 and the LA 513, and stores the same in the APP 514.

The above has described the contents of the process performed in the storage system according to the present embodiment. As have been described, when the initialization process is executed, the FMPK 200 according to the present embodiment makes each sector become the state where data is not written by setting the allocation status 603 of the respective sectors to “0”. But in the initialization process, data will not be written to the FM chips 210. When the DKC 10 issues a read request to each sector immediately after initialization has been performed, the FMPK 200 creates data in an initialized state and returns the same to the DKC 10, according to which a memory area in a visually initialized state is created. Therefore, the FMPK 200 according to the present embodiment can perform initialization of the FMPK 200 in an extremely short time.

In the case of the storage system required to have high reliability, when storing data to the memory device, data is stored in the memory device after the inspection code (DIF) is added to the data. Since information for verifying validity of data access location (such as the data storage destination address) is included in the DIF, the value that the DIF may take can be differed depending on the configuration of the storage system or the volume, or the data storage location. The FMPK 200 according to the present embodiment is configured to be able to generate information to be stored in the DIF, by acquiring the configuration information. Thus, there is no need to receive initialization data from the storage controller 10 during initialization and write it to the FM chips 210.

The present embodiment has been described above, but the embodiment is a mere example for illustrating the present invention, and it is not intended to limit the scope of the invention in any way. The present invention can be executed in various other forms.

### REFERENCE SIGNS LIST

1: Storage system, 2: host, 3: SAN, 10: storage controller, 11: processor (CPU), 12: host IF, 13: device IF, 14: memory, 16: cross-coupling switch, 20: RAID group, 200: FMPK, 200′: HDD, 201: FM controller, 202: memory, 203: processor, 204: compression expansion circuit, 205: format data generation circuit, 206: SAS-CTL, 207: FM-IF, 208: internal connection switch, 210: FM chip

1. A storage device comprising a plurality of memory devices including a device controller and a nonvolatile storage medium, and a storage controller,
wherein the memory device is configured to provide a storage space to the storage controller, the storage space comprising a plurality of sectors, each of the plurality of sectors being composed of a write data memory region and a memory region for storing an inspection code of data stored in the write data memory region, and
if the memory device receives a read request from the storage controller to a first sector that has not been subjected to write from the storage controller among the plurality of sectors, the memory device generates a predetermined pattern data and the inspection code, and returns information having added the inspection code to the predetermined pattern data to the storage controller.

2. The storage device according to claim 1,
wherein the inspection code includes an error detecting code generated using data stored in the write data memory region, and information related to a storage location of the data.

3. The storage device according to claim 2,
wherein if a write request and a write data are received from a host computer, the storage controller generates the inspection code based on a location information included in the write request and the write data, and adds the inspection code to the write data and transmits the same to the memory device, and
the memory device stores the write data and the inspection code to the nonvolatile storage medium.

4. The storage device according to claim 2,
wherein if the memory device receives a write request to the sector, the memory device maps a memory area of the nonvolatile storage medium to the sector, stores the write data and the inspection code to the memory area being mapped, and records information that the write data has been written to the sector and information of the memory area mapped to the sector to a mapping information.

5. The storage device according to claim 4,
wherein if the memory device receives a read request to the sector to which the storage controller had written among the plurality of sectors, the memory device returns data stored in the memory area mapped to the sector to the storage controller.

6. The storage device according to claim 4,
wherein if the device controller receives an initialization instruction from the storage controller, the device controller clears the mapping information.

7. The storage device according to claim 6,
wherein the nonvolatile storage medium is a flash memory comprising a plurality of blocks which are data erase units, and
if the device controller receives the initialization instruction, the device controller erases a predetermined number of the blocks among the plurality of blocks, and responds to the storage controller that a process related to the initialization instruction has been completed.

8. The storage device according to claim 6,
wherein the storage controller forms one or more logical storage spaces using the storage space provided by the plurality of memory devices,
while generating the inspection code, the storage controller is configured to store an identifier of the logical storage space in the inspection code,
while receiving the initialization instruction from the storage controller, the memory device receives the identifier of the logical storage space to which the memory device belongs, and
while generating the inspection code, the memory device stores the received identifier in the inspection code.

9. A memory device connected to a storage device comprising a device controller and a nonvolatile storage medium;
the device controller being configured to provide a storage space comprising a plurality of sectors to the storage device; each of the plurality of sectors being composed of a write data memory region and a memory region for storing an inspection code of data stored in the write data memory region,
wherein if the device controller receives a read request from the storage device to a first sector that has not been subjected to write from the storage device among the plurality of sectors, the device controller generates a predetermined pattern data and the inspection code, and returns information having added the inspection code to the predetermined pattern data to the storage device.

10. The memory device according to claim 9,
wherein the inspection code includes an error detecting code generated using data stored in the write data memory region, and information related to a storage location of the data.

11. The memory device according to claim 10,
wherein if the device controller receives a write request to the sector, the device controller maps a memory area of the nonvolatile storage medium to the sector, stores the write data and the inspection code to the memory area being mapped, and records information that the write data has been written to the sector and information of the memory area mapped to the sector to a mapping information.

12. The memory device according to claim 11,
wherein if the device controller receives a read request to the sector to which the storage controller had written among the plurality of sectors, the device controller returns data stored in the memory area mapped to the sector to the storage device.

13. The memory device according to claim 11,
wherein if the device controller receives an initialization instruction from the storage device, the device controller clears the mapping information.

14. The memory device according to claim 13,
wherein the nonvolatile storage medium is a flash memory comprising a plurality of blocks which are data erase units, and
if the device controller receives the initialization instruction, the device controller erases a predetermined number of the blocks among the plurality of blocks, and responds to the storage device that a process related to the initialization instruction has been completed.
